(19) United States
(12) Patent Application Publication
(10) Pub. No.: US 2015/0009742 A1
(43) Pub. Date: Jan. 8, 2015

(54) SEMICONDUCTOR MEMORY DEVICE HAVING IMPROVED FUSE SENSING RELIABILITY IN SLOW POWER-UP OPERATION AND METHOD FOR READING FUSE BLOCK THEREBY

(71) Applicant: Samsung Electronics Co., Ltd., Suwon-si (KR)

(72) Inventors: Kyu-Chang KANG, Seoul (KR); Jung-Bum SHIN, Osan-si (KR); Chan-Yong LEE, Suwon-si (KR)

(73) Assignee: Samsung Electronics Co., Ltd., Suwon-si (KR)

(21) Appl. No.: 14/223,867

(22) Filed: Mar. 24, 2014

(30) Foreign Application Priority Data
Jul. 5, 2013 (KR) 10-2013-0079227

(51) Int. Cl. G11C 14/00; G11C 5/14; G11C 17/16

(52) U.S. Cl. CPC G11C 14/0009; G11C 17/16; G11C 5/14
USPC 365/96

(57) ABSTRACT

Provided is a semiconductor memory device with improved fuse sensing reliability during a slow power-up operation. The semiconductor memory device may include a memory cell array including a normal memory cell array and a spare memory cell array; an anti-fuse circuit supplied with a first voltage and configured to store fail address information associated with a defective memory cell in the normal memory cell array and configured to sense the fail address information in response to a clock signal applied during a power-up period; and a fuse read circuit including a clock generator supplied with a second voltage, the fuse read circuit configured to detect respective levels of the first and second voltages during the power-up period to generate the clock signal and to read the sensed fail address information from the anti-fuse circuit in response to the clock signal.

### CROSS-REFERENCE TO RELATED APPLICATIONS

This US non-provisional patent application claims the benefit of priority under 35 USC §119 to Korean Patent Application No. 10-2013-0079227, filed on Jul. 5, 2013, the entirety of which is hereby incorporated by reference.

### BACKGROUND

The disclosed embodiments relate to semiconductor memory fields and, more particularly, to semiconductor memory devices having improved fuse sensing reliability and methods for reading fuse blocks thereby.

In many memory systems, even when only one of numerous memory cells in a semiconductor memory device is defective, the semiconductor memory device is not capable of performing a desired function and is treated as a bad one. However, it is inefficient in terms of yield to treat a semiconductor memory device as a defective memory device when only a small number of memory cells are defective.

Accordingly, a typical semiconductor memory device may include a spare memory cell array. When a defect occurs in normal memory cells in a normal memory cell array, the semiconductor memory device is repaired as a non-defective memory device by replacing the defective memory cells in the normal memory cell array with spare memory cells in the spare memory cell array. A defect repair operation performed after a package process is called post-package repair. In this repair operation, the yield of the semiconductor memory device may be further improved.

During a conventional repair or post-package repair operation, defective memory cells may be replaced with spare memory cells in units of rows/columns. An anti-fuse may be generally used as a program element for storing a fail address to perform the replacement operation. For example, when a defective memory cell is detected through a test after wafer processing is terminated, a fail address indicating an address of a defective memory cell is programmed, for example, by rupturing anti-fuses. Thus, a row/column of a spare memory cell is activated using information programmed into the anti-fuses when an address to access the defective memory cell is input.

An anti-fuse block including the anti-fuses starts to sense fail address information stored in the anti-fuses when a predetermined time lapses after a power-up signal of the semiconductor memory device is tripped. In general, it is difficult to read the fail address information when a power up operation is slow.

### SUMMARY

Exemplary embodiments provide a semiconductor memory device and an anti-fuse block read method of the semiconductor memory device.

According to exemplary embodiments, a semiconductor memory device may include a memory cell array including a normal memory cell array and a spare memory cell array; an anti-fuse circuit supplied with a first voltage and configured to store fail address information associated with a defective memory cell in the normal memory cell array and configured to sense the fail address information in response to a clock signal applied during a power-up period; and a fuse read circuit including a clock generator supplied with a second voltage, the fuse read circuit configured to detect respective levels of the first and second voltages during the power-up period, to generate the clock signal, and to read the sensed fail address information from the anti-fuse circuit in response to the clock signal. The clock signal has a period that varies in response to the detected levels of the first and second voltages.

According to an exemplary embodiment, the defective memory cell may be a dynamic random access memory (DRAM) cell.

According to an exemplary embodiment, the clock generator may be configured to generate the clock signal, and the fuse read circuit may include a clock period control circuit configured to detect respective levels of the first voltage and second voltage during the power-up period, and to generate a clock period control signal based on a result of the detection.

According to an exemplary embodiment, the fuse read circuit may further include a fuse information storage circuit configured to store the sensed fail address information in response to the clock signal.

According to an exemplary embodiment, the fuse information storage circuit may include a shift register.

According to an exemplary embodiment, the clock generator may be a voltage control type oscillator configured to generate the clock signal whose frequency varies depending on the detected level of the first voltage.

According to an exemplary embodiment, the clock period control circuit may include a first delay part supplied with the second voltage and configured to receive and delay the clock signal; a second delay part supplied with the first voltage and configured to receive and delay the clock signal; and a phase detector configured to compare a phase of a first output clock delayed by the first delay part with a phase of a second output clock delayed by the second delay part to generate the clock period control signal.

According to an exemplary embodiment, the phase detector may generate the clock period control signal that causes the clock signal to have a period longer than a reference period when the phase of the first output clock is ahead of the phase of the second output clock.

According to an exemplary embodiment, the phase detector may be configured to generate the clock period control signal that causes the clock signal to have a period equal to or shorter than a reference period when the phase of the first output clock is lagged behind the phase of the second output clock.

According to an exemplary embodiment, a sensing speed of the fail address information may be slow when a level of the first voltage is lower than a level of the second voltage during the power-up period.

According to another exemplary embodiments, a method of reading data from an anti-fuse circuit of a semiconductor memory device is provided. The method may include, during a power-up operation mode, applying a first voltage to a clock generator of the semiconductor memory device and a second voltage to the anti-fuse circuit; controlling a frequency of a driving clock applied to an anti-fuse circuit to be less than a reference frequency of the driving clock when a level of the second voltage is less than a level of the first voltage during the power-up operation mode; and reading the data of the anti-fuse circuit in response to the driving clock.

According to an exemplary embodiment, a level of the second voltage may be higher than a level of the first voltage after the power-up operation mode is terminated.

According to an exemplary embodiment, a speed of reading the data may be reduced by decreasing a frequency of the driving clock.

According to still another exemplary embodiments, a method of reading data from a fuse storage circuit of a memory device is provided. The fuse storage circuit includes a plurality of fuses. The method includes initiating a power-up operation of the memory device by providing first and second voltages to the fuse storage circuit and a clock generator of the memory device, respectively; and during the power-up operation, generating a clock signal by the clock generator, the clock signal having a period; and reading the data stored in the plurality of fuses of the fuse storage circuit in response to the clock signal. The period of the clock signal is longer than a reference period when a level of the first voltage is less than a level of the second voltage.

### BRIEF DESCRIPTION OF THE DRAWINGS

FIG. 1 is an exemplary schematic block diagram of a semiconductor memory device according to one embodiment.

FIG. 2 comparatively illustrates differentiation of anti-fuse sensing periods according to the control of a fuse read circuit in FIG. 1.

FIG. 3 is a block diagram of the fuse read circuit in FIG. 1 according to one embodiment.

FIG. 4 is an exemplary detailed circuit diagram of a clock generator in FIG. 3 according to one embodiment.

FIG. 5 is an exemplary detailed circuit diagram of a clock period control part in FIG. 3 according to one embodiment.

FIG. 6 is an exemplary timing diagram of a sensing enable signal according to FIG. 1 during tripping of a power-up signal.

FIG. 6A is an exemplary diagram illustrating power supply voltages of FIG. 1 during a power-up operation according to one embodiment.

FIG. 7 is an exemplary diagram of frequency variation of a driving clock generated by FIG. 4 according to one embodiment.

FIG. 8 is a flowchart illustrating an anti-fuse sensing method according to FIG. 1.

FIG. 9 is an exemplary diagram of driving clocks for sensing anti-fuses that are variously formed depending on detected levels of applied voltages during the power-up in FIG. 1.

FIG. 10 is a block diagram illustrating a memory system according to certain embodiments.

FIG. 11 is a block diagram illustrating a handheld electronic device according to certain embodiments.

FIG. 12 is a block diagram illustrating an electronic system according to certain embodiments.

FIG. 13 is a block diagram illustrating a semiconductor chip that is mounted on a semiconductor wafer according to certain embodiments.

FIG. 14 is a block diagram illustrating a mobile device according to certain embodiments.

FIG. 15 is a block diagram illustrating a memory card according to certain embodiments.

FIG. 16 is a block diagram illustrating a computing device according to certain embodiments.

### DETAILED DESCRIPTION

Various exemplary embodiments will be described in more detail with reference to the accompanying drawings. It should be noted, however, that the invention is not limited to the following exemplary embodiments, and may be implemented in various forms. Accordingly, the exemplary embodiments are provided only to disclose examples of the invention and to let those skilled in the art understand the nature of the invention. In the drawings, the size and relative sizes of layers and regions may be exaggerated for clarity. Like numbers refer to like elements throughout.

In the specification, it will also be understood that when an element or lines are referred to as being “on” a target element block, it can be directly on the target element block, or intervening another element may also be present. In the drawings, thicknesses of elements are exaggerated for clarity of illustration.

The terms used in the specification are for the purpose of describing particular embodiments only and are not intended to be limiting of the invention. As used in the specification, the singular forms “a”, “an” and “the” are intended to include the plural forms as well, unless the context clearly indicates otherwise. It will be further understood that the terms such as “comprises,” “comprising,” “includes,” and/or “including,” when used in the specification, specify the presence of stated features, integers, steps, operations, elements, and/or components, but do not preclude the presence or addition of one or more other features, integers, steps, operations, elements, components, and/or groups thereof.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. Unless indicated otherwise, these terms are only used to distinguish one element from another. For example, a first signal could be termed a second signal, and, similarly, a second signal could be termed a first signal without departing from the teachings of the disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

Each embodiment described and exemplified herein may include a complementary embodiment thereof. Note that the DRAM devices and their basic data access operations, read and write operations, and internal function circuits will not be described to avoid ambiguity of the feature of the invention.

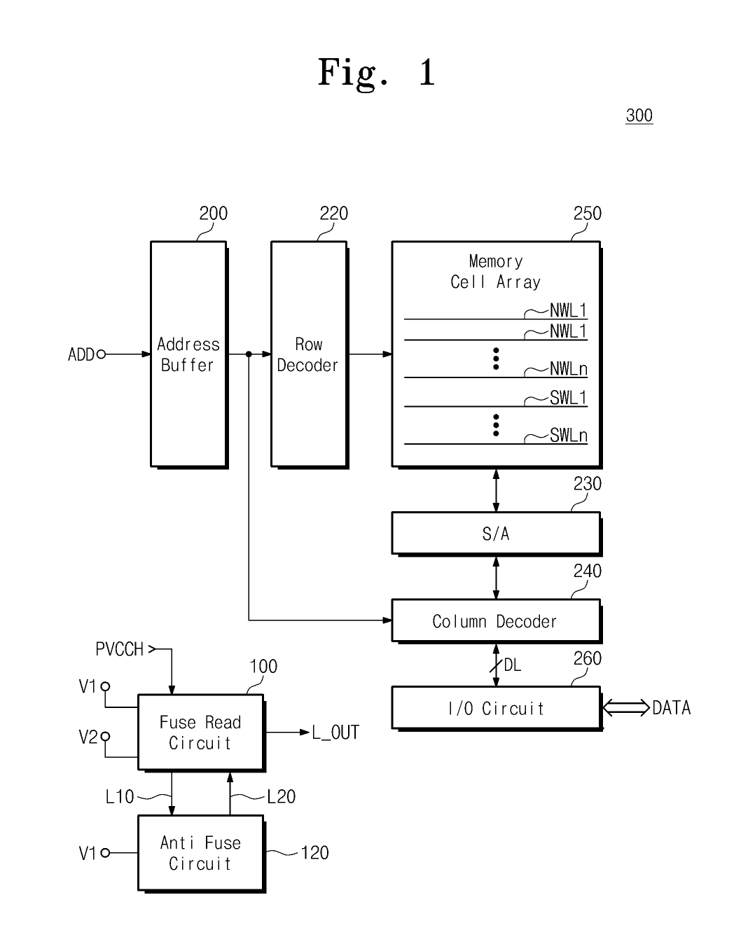

FIG. 1 is an exemplary schematic diagram of a semiconductor memory device 300 according to one embodiment. As illustrated, the semiconductor memory device 300 includes a memory cell array 250, an address buffer 200, a row decoder 220, a column decoder 240, a sense amplifier 230, and an input/output (I/O) circuit 260. Also the semiconductor memory device 300 includes an anti-fuse circuit 120 and a fuse read circuit 100.

The memory cell array 250 includes a normal memory cell array including normal memory cells (also referred to as primary memory cells) connected to normal wordlines NWL1-NWLn and a spare memory cell array including spare memory cells connected to spare wordlines SWL1-SWLn.

The anti-fuse circuit 120 includes an anti-fuse array including a plurality of anti-fuses, a program circuit to program a fail address by accessing the anti-fuses in the anti-fuse array, and a sensing circuit to sense programmed fail address information by accessing the anti-fuses in the anti-fuse array during a power-up period of the semiconductor memory device 300.

Accordingly, the anti-fuse circuit 120 stores fail address information associated with a defective memory cell in the normal memory array and is configured to sense the fail address information in response to a driving clock applied during the power-up period.

The fuse read circuit 100 detects a level of a first voltage V1 applied to the fuse read circuit 100 during the power-up period and generates the driving clock whose period is adjusted depending on the detected level. The fuse read circuit 100 allows the sensed fail address information to be read from the anti-fuse circuit 120 in response to the driving clock.

Dynamic random access memories (DRAMs) have been widely employed in mobile electronic devices such as smart phones. For example, in such a mobile DRAM, sensing of fail address information stored in anti-fuses in an anti-fuse array may start unconditionally when a predetermined time lapses after a power-up signal PVCCH is tripped.

Accordingly, a voltage level is relatively low on slow power-up where a power-up slope is gentle and thus reliability of sensing information may be deteriorated when the fail address information is sensed.

In FIG. 1, the fuse read circuit 100 is prepared to improve or optimize the sensing reliability. The fuse read circuit 100 detects the level of the first voltage V1. When it is determined to be slow power-up, the fuse read circuit 100 applies the driving clock whose period is adjusted to be relatively long to the anti-fuse circuit 120 through a line L10. The anti-fuse circuit 120 receives the driving clock of a relatively slow frequency to sense fail address information. The relatively slowly sensed fail address information may be provided to the fuse read circuit 100 through the line L20. The sensed fail address information may be stored, for example, in a latch or a register in the fuse read circuit 100.

In one embodiment, when the level of a powered-up voltage is detected and the detected voltage does not reach a predetermined voltage, it is determined to be slow power-up. In this case, fail address information stored in anti-fuses are sensed relatively slowly. For example, if a sensing speed of the fail address information is slower than a normal sensing speed, sensing reliability of the fail address information may be improved.

After a power-up operation period is terminated and a row address to select a normal wordline NWL1 is applied during a normal operation period, the row address is compared with the fail address information read by the fuse read circuit 100. In the comparison operation, when the normal wordline NWL1 is determined to be a defective wordline, a spare wordline SWL1 may be activated by performing a repair operation instead of the normal wordline NWL1.

In FIG. 1, the first voltage V1 may be an external power supply voltage of the semiconductor memory device 300, and a second voltage V2 may be a driving voltage to generate the driving clock in the fuse read circuit 100.

As a fail address, an address of a row to which a defective normal memory cell belongs is programmed into the anti-fuse circuit 120. Any one of spare rows including spare memory cells is set as a spare word line to replace the defective row.

When an input address applied to a row decoder and the fail address match each other, a spare wordline is activated instead of a normal wordline.

In one example, an anti-fuse memory cell of an anti-fuse circuit may generally comprise an anti-fuse and pull-up and pull-down driving circuits.

In general, when a laser fuse is used, programming is performed by laser cutting of a fuse comprising a meal line. However, there is a limitation that a regular interval is ensured between fuses to suppress a damage caused by the laser fuse. Irrespective of the advance in memory manufacturing process technology such as a metal oxide semiconductor (MOS) process, there is a limitation in increasing the integration density of a laser fuse and the laser fuse cannot be used after a memory chip is packaged.

An electrical fuse (E-fuse) and an anti-fuse use an electrical signal to perform programming. For example, the E-fuse and the anti-fuse may be used even after packaging because they are activated or deactivated by an electrical signal, and the size of a fuse circuit may decrease with process scale-down.

Programming using an E-fuse is performed by applying high current to a fuse. Although the E-fuse may be ruptured by externally applying a control signal even after packaging, a relatively large-sized driver may be needed to allow large amount of current to flow to the E-fuse.

Unlike the programming using an E-fuse, programming using an anti-fuse is performed by applying a high voltage to both ends of the anti-fuse. In general, an anti-fuse may be implemented with a capacitor element. When a high voltage is applied to both ends of the anti-fuse, a dielectric in a capacitor is destroyed to act as a conductor. Similar to the E-fuse, the anti-fuse is ruptured by externally applying a control signal even after packaging.

As described in the disclosed embodiments, an anti-fuse is used in a fuse block. However, it should be understood that an E-fuse may be used in the fuse block.

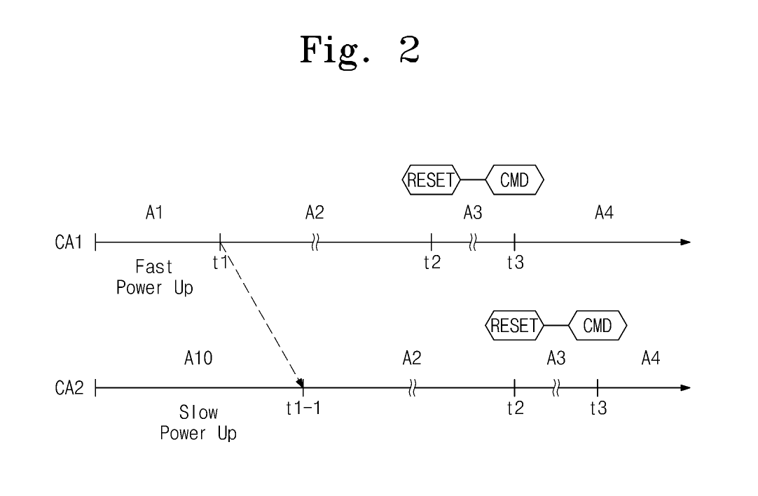

FIG. 2 comparatively illustrates differentiation of anti-fuse sensing periods according to the control of a fuse read circuit in FIG. 1.

Referring to FIG. 2, a first case CA1 indicates a memory operating period on fast power-up or normal power-up, and a second case CA2 indicates a memory operating period on slow power-up.

For example, in the first case CA1, anti-fuse sensing is terminated during a period A1. Meanwhile, in the second case CA2, anti-fuse sensing is terminated during a period A10. In general, the specification of a DRAM may be, for example, 200 microseconds until a reset signal is applied, and its start time point is a time point following stabilization of a power level. Therefore, a counting start time point of the specification is t1 in the first case CA1 while a counting start time point of the specification is t1-1 in the second case CA2. As a result, the specification is satisfied even when a sensing operation is made slow on the slow power-up. In FIG. 2, a period A2 may be 200 microseconds, as determined in the specification. A period A3 is a delay time between a reset signal and a command. During a period A4, a normal operation is performed to access a memory cell.

As a result, according to the disclosed embodiments, anti-fuse sensing is done during the period A10 of the second case CA2 on the slow power-up to improve sensing reliability.

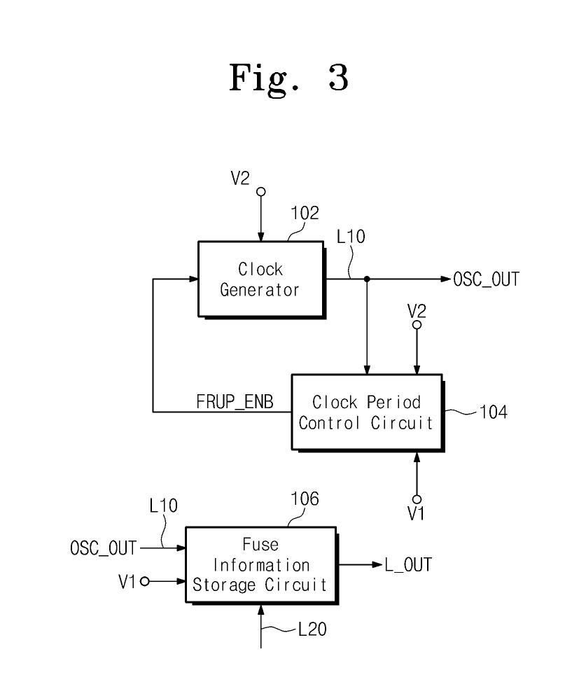

FIG. 3 is a block diagram of the fuse read circuit 100 in FIG. 1 according to one embodiment. As illustrated, the fuse read circuit 100 includes a clock generator 102 and a clock period control circuit 104. Also the fuse read circuit 100 may include a fuse information storage circuit 106.

The clock generator 102 receives a driving voltage V2 as an operating power source to generate a driving clock OSC_OUT through a line L10. A frequency (or period) of the driving clock OSC_OUT varies depending on a clock period control signal FRUP_ENB.

For example, when a value of the clock period control signal FRUP_ENB is greater than a reference value, the period of the clock OSC_OUT is longer than a reference period. When the value of the clock period control signal FRUP_ENB converges to the reference value, the period of the driving clock OSC_OUT is close to the reference period.

The period of the driving clock OSC_OUT varies depending on how much larger the value of the clock period control signal FRUP_ENB is than the reference value.

The clock period control part 104 detects a level of a first voltage V1 applied to the fuse information storage circuit 106 and a level of the driving voltage V2 during a power-up period and generates a clock period control signal FRUP_ENB that causes the driving clock OSC_OUT to have a period longer than a reference period when the detected level of the first voltage V1 is equal to or less than the detected level of the driving voltage V2.

The fuse information storage 106 receives the first voltage V1 and functions as a fuse information storing part and stores the fail address information sensed in the anti-fuse circuit 120 in response to the driving clock OSC_OUT.

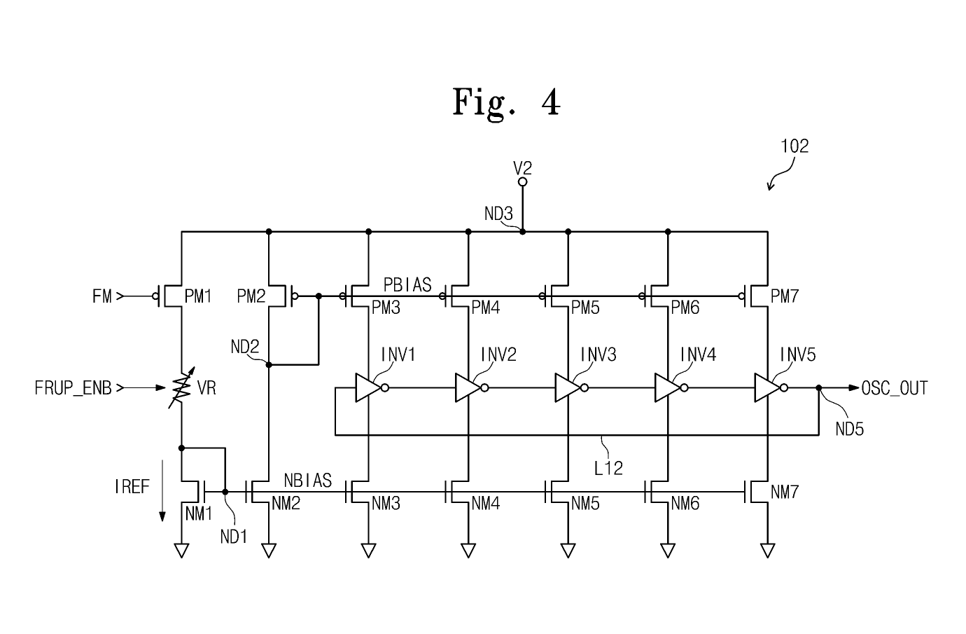

FIG. 4 is an exemplary detailed circuit diagram of the clock generator 102 in FIG. 3 according to one embodiment. Referring to FIG. 4, the clock generator 102 has a voltage control type oscillator structure to generate the driving clock OSC_OUT whose frequency varies depending on the respective detected levels of the first voltage V1 and the driving voltage V2.

The clock generator 102 includes a PBIAS generation part including a plurality of PMOS transistors PM1-PM7, an NBIA generation part including a plurality of NMOS transistors NM1-NM7, an oscillation part including a plurality of inverters INV1-INV5 connected in cascade, and a variable adjustment part to adjust biasing current IREF by a variable resistor VR.

The level of an NBIAS voltage formed at a node ND1 in FIG. 4 is decided by a value of the clock period control signal FRUP_ENB. As a result, since flow of the biasing current IRF increases when the value of the clock period control signal FRUP_ENB is relatively great, the level of the NBIAS voltage at the node ND1 drops.

The level of a PBIA voltage formed at a node ND2 in FIG. 4 is also decided by the value of the clock period control signal FRUP_ENB. As a result, since the level of the NBIAS voltage at the node ND1 drops when the value of the clock period control signal FRUP_ENB is relatively great, the NMOS transistor NM2 is turned on relatively weakly. Thus, the level of the PBIAS voltage formed at the node ND2 rises.

A voltage V2 formed at a node ND3 in FIG. 4 is a voltage applied on power-up, and the driving clock OSC_OUT whose frequency is controlled by the PBIAS and the NBIAS is generated at a node ND5 to which an output feedback line L12 is connected.

A signal FM applied to a gate of the PMOS transistor PM1 in FIG. 4 is a flag signal to enable the operation of the clock generator 102.

As shown in FIG. 4, the anti-fuse circuit 120 may receive the driving clock OSC_OUT of relatively slow frequency on slow power-up to sense fail address information according to a voltage control type oscillator whose frequency is controlled by the clock period control signal FRUP_ENB. When the sensing is performed at lower speed than normal sensing speed, sensing reliability of the fail address information is improved.

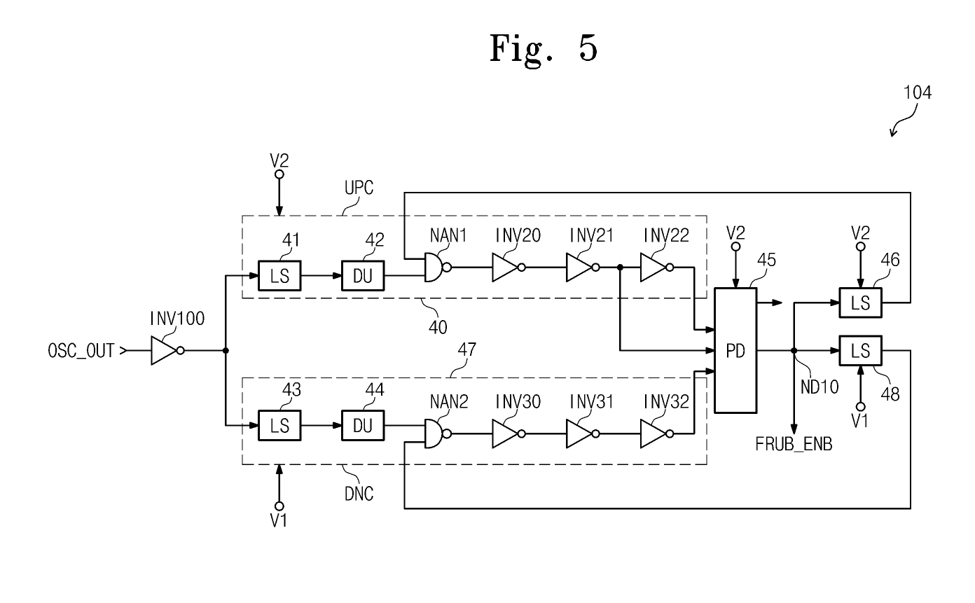

FIG. 5 is an exemplary detailed circuit diagram of the clock period control part 104 in FIG. 3 according to one embodiment. As illustrated, the clock period control part 104 may include a first delay part 40, a second delay part 47, and a phase detector 45.

The first delay part 40 receives the driving clock OSC_OUT and delays the driving clock OSC_OUT with the driving voltage V2. The first delay part 40 may include a level shifter 41, a delay unit 42, a NAND gate NAN1, and inverters INV20-INV22. The first delay part 40 receives the driving voltage V2 as an operation power source.

The second delay part 47 receives the driving clock OSC_OUT and delays the driving clock OSC_OUT when the first voltage V1 is lower than the driving voltage V2. The second delay part 47 may include a level shifter 43, a delay unit 44, a NAND gate NAN2, and inverters INV30-INV32. The second delay part 47 receives the first voltage V1 as an operation power source.

The phase detector 45 compares a phase of a first output clock delayed by the first delay part 40 and a phase of a second output clock delayed by the second delay part 47 to generate the clock period control signal FRUP_ENB.

The phase detector 45 generates the clock period control signal FRUP_ENB that makes the driving clock OSC_OUT to have a period longer than a reference period when the phase of the first output clock is ahead of the phase of the second output clock. When generating the clock period control signal FRUP_ENB that makes the driving clock OSC_OUT to have a period longer than the reference period, sensing speed of the fail address information is relatively reduced during the power-up period to improve sensing reliability.

In addition, the phase detector 45 generates the clock period control signal FRUP_ENB that sets the driving clock OSC_OUT to have a reference period when the phase of the first out clock lags behind the phase of the second output clock.

In FIG. 5, a reference numeral 46 represents a level shifter that operates by receiving the second voltage V2 and a reference numeral 48 represents a level shifter that operates by receiving the first voltage V1.

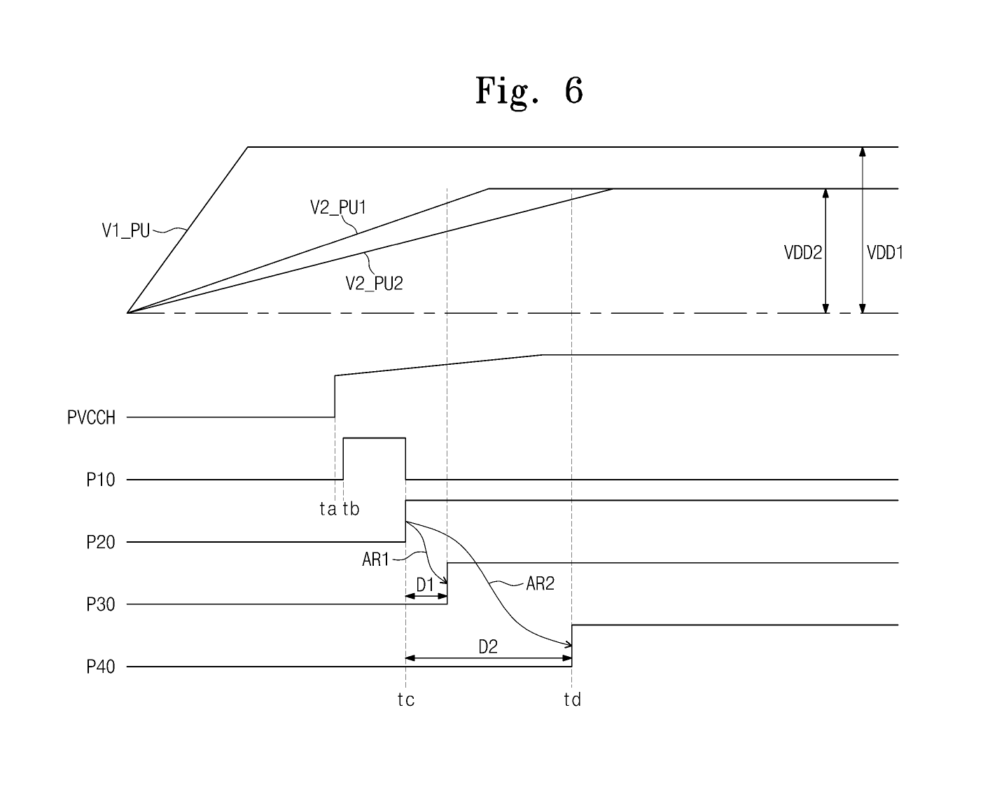

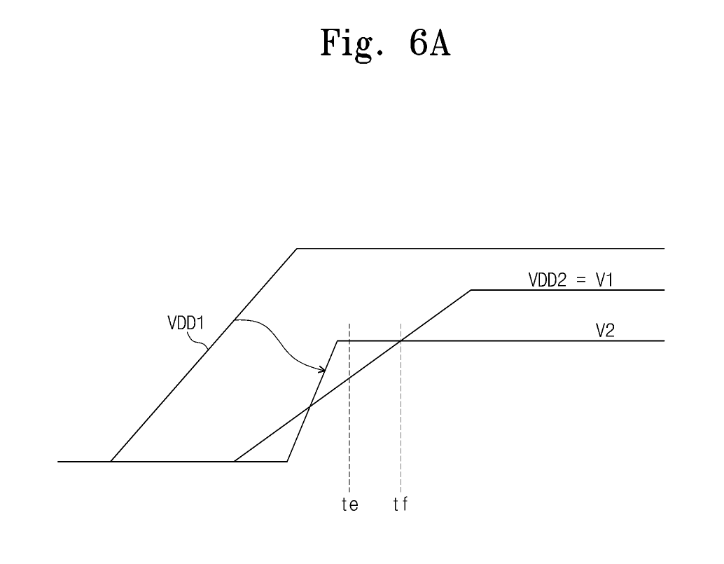

FIG. 6 is an exemplary timing diagram of a sensing enable signal according to FIG. 1 during tripping of a power-up signal.

Referring to FIG. 6, voltage levels of a voltage VDD1 and a voltage VDD2 are comparatively shown. The voltage VDD1 may be a first external power supply voltage applied to the semiconductor memory device 300 and may internally generate the second voltage V2 of FIGS. 1 and 3-5. The voltage VDD2 may be a second external power supply voltage and may be referred to as the first voltage V1 of FIGS. 1 and 3-5.

For example the first voltage V1 may be applied to the anti-fuse circuit 120 and the fuse information storage circuit 106 of FIGS. 1 and 3, the second voltage V2 may be an operation power supply voltage of the clock generator 102 to generate the driving clock OSC_OUT of FIG. 4.

Exemplary voltage levels of the voltage VDD1 and the voltage VDD2 may be 1.8 volt and 1.2 volt, respectively.

For example, in the case that a power-up slope of the voltage VDD1 is indicated by a reference numeral V1_PU and a power-up slope of the voltage VDD2 is indicated by a reference numeral V2_PU1, let it be assumed that this case is referred to as normal power-up or fast power-up. In the case that the power-up slope of the voltage VDD1 is indicated by a reference numeral V1_PU and a power-up slope of the voltage VDD2 is indicated by a reference numeral V2_PU2, power-up of the voltage VDD2 may be slow power-up.

If a sensing enable signal of an anti-fuse is generated and sensing is performed with the driving clock OSC_OUT oscillating with a normal frequency even when the power-up of the voltage VDD2 is slow power-up, reliability of sensing information may be deteriorated.

Accordingly, in the disclosed embodiments, sensing operation may be slowly performed by making the period of the driving clock OSC_OUT relatively long when the power-up slope of the voltage VDD2 is slow power-up as indicated by the reference numeral V2_PU2.

If necessary, a sensing enable signal of an anti-fuse may not be generated as a waveform P30 but be generated at a time point td as a waveform P40.

In FIG. 6, PVCCH represents a power-up signal that transitions to a high level when a rising level of a voltage reaches a specific level during a power-up period. The waveform P10 is a pumping power setting signal generated in response to the power-up signal, the waveform P20 is a sensing ready signal, and a waveform P30 is a sensing enable signal. The sensing enable signal is generated with a delay time D1 in response to the waveform P20, as indicated by an arrow AR1.

In an embodiment, as indicated by an arrow AR2, a sensing enable signal of an anti-fuse is generated as a waveform P40 at a time point td that is delayed by a delay D2 from a time point tc. If a sensing start time point is postponed and a sensing operation is slowly performed on slow power-up, sensing reliability may be further improved.

FIG. 6A is an exemplary diagram illustrating power supply voltages of FIG. 1 during a power-up operation according to one embodiment.

Referring to FIG. 6A, a first external voltage VDD1 may be applied to the semiconductor memory device 300 of FIG. 1 and may internally generate the second voltage V2 of FIGS. 1 and 3-5. The second voltage V2 may be applied to the clock generator of FIG. 4 and the clock period control part 104 in FIG. 5. A second external voltage VDD2 may be applied to the anti-fuse circuit 120 and the fuse information storage circuit 106 of the semiconductor memory device 300 of FIGS. 1 and 3. The second external voltage VDD2 may be the first voltage V1 of FIGS. 1 and 3.

We may assume that a level of the first voltage V1 is the same as a level of the second voltage V2 at time point tf as shown in FIG. 6A. In this case, a period of the clock signal OSC_OUT may need to be delayed at time point to before the time point t1 to read the failed address stored in the anti-fuse circuit of FIG. 1.

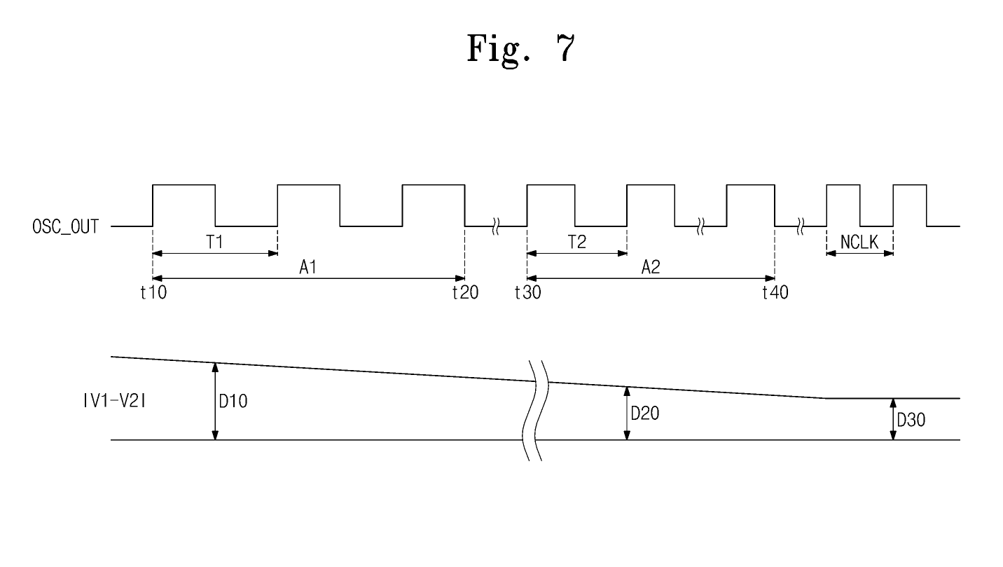

FIG. 7 is an exemplary diagram of frequency variation of a driving clock generated by FIG. 4 according to one embodiment. Referring to FIG. 7, when a level of the first voltage V1 is lower than a level of the second voltage V2, the smaller a difference between the levels of the first voltage V1 and the second voltage V2, the closer a period of the driving clock OSC_OUT is to a period of a reference driving clock NCLK. For example, the difference between the levels of the first voltage V1 and the second voltage V2 is D10 in case of slow power-up and is D30 in case of normal power-up.

As a result, the period of the driving clock OSC_OUT is T1 when the difference between the levels of the first voltage V1 and the second voltage V2 is D10. In addition, the period of the driving clock OSC_OUT is T2 shorter than T1 when the difference between the levels of the first voltage V1 and the second voltage V2 is D20. Accordingly, a failed address is sensed relatively slowly by the driving clock OSC_OUT having the period T1 in case of slow power-up. In addition, the failed address is sensed relatively quickly by the driving clock OSC_OUT having the normal period NCLK in case of normal power-up.

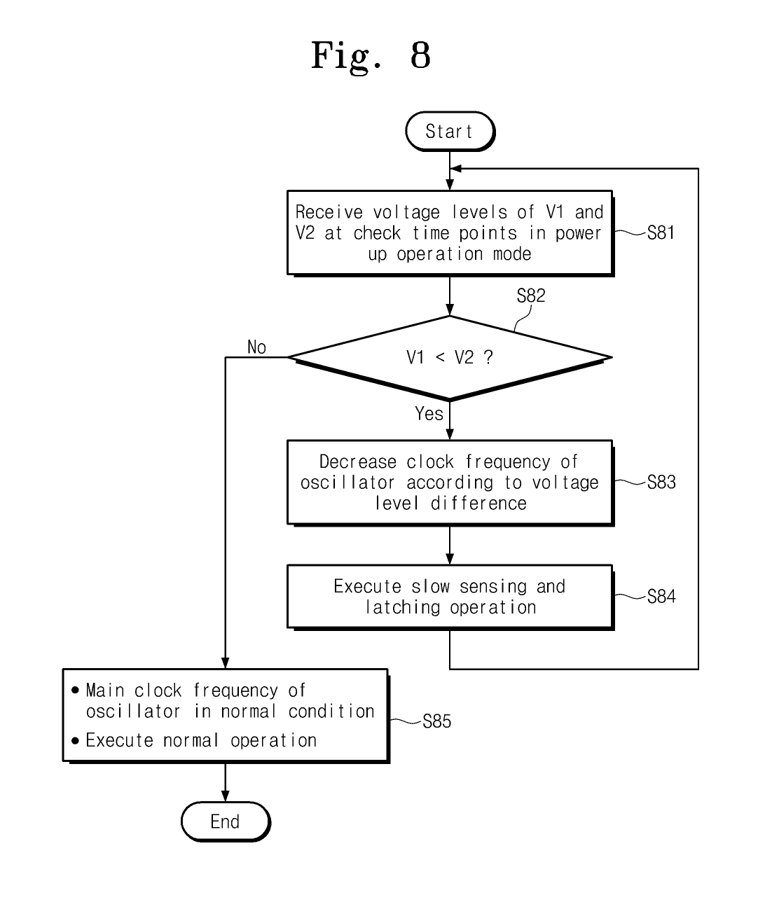

FIG. 8 is a flowchart illustrating an anti-fuse sensing method according to FIG. 1. Referring to FIG. 8, anti-fuse sensing operations are shown. The operations shown in FIG. 8 may be performed by a semiconductor memory device in FIG. 1 which includes the fuse read circuit 100

At S81, the clock period control part 104 in FIG. 3 receives the levels of the first and second voltages V1 and V2 during a power-up operation mode. The levels of the first and second voltages V1 and V2 are received at check time points. For example, one of the check time points may be the time point tc and tf in FIGS. 6 and 6A, respectively.

At S82, the clock period control part 104 in FIG. 3 checks whether the level of the first voltage V1 is less than a level of the second voltage V2.

When the level of the first voltage V1 is less than the level of the second voltage V2, it is checked as slow power-up. Thus, the flow proceeds to S83.

When the level of the first voltage V1 is equal to or greater than the level of the second voltage V2, it is checked as normal power-up. Thus, the flow proceeds to S85.

At S83, a clock frequency of an oscillator that is a clock generator decreases according to the voltage level difference. For example, the frequency of the driving clock OSC_OUT is made relatively slow.

When the clock frequency decreases, slow sensing and slow latch operations are executed at S84. Thus, a sensing operation of the failed address and a read operation may be slowly executed to ensure reliability.

Following S84, the flow may return to S81. The difference between the levels of the first and second voltages V1 and V2 are checked at another check time point. When the level of the first voltage V1 is checked to be equal to or greater than the level of the second voltage V2, the flow proceeds to S85.

At S85, the clock frequency of the oscillator is maintained under a normal condition and a normal operation is executed. For example, the driving clock OSC_OUT is generated with a normal clock frequency when slow power-up is not any longer.

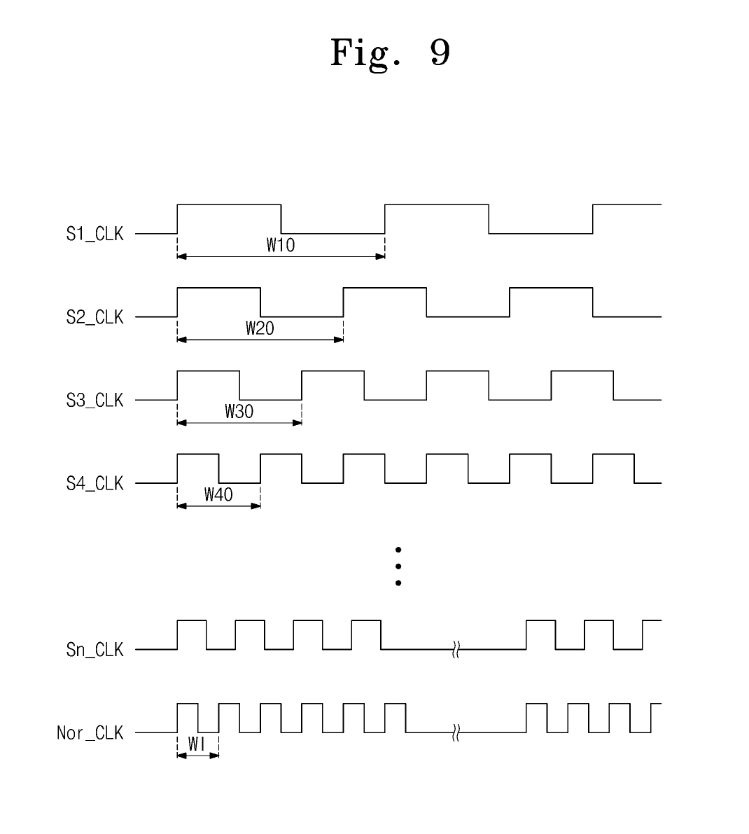

FIG. 9 is an exemplary diagram of driving clocks for sensing anti-fuses that are variously formed depending on detected levels of applied voltages during the power-up in FIG. 1. Referring to FIG. 9, examples of a driving clock generated on slowest power-up to a driving clock generated on normal power-up are shown.

A waveform S1_CLK having a period W10 indicates a driving clock generated on slowest power-up.

A waveform S2_CLK having a period W20 indicates a driving clock generated on slow power-up that is faster than the waveform S1_CLK.

A waveform Nor_CLK having a period WI indicates a driving clock generated on fast power-up or normal power-up.

Likewise, fail address information stored in an anti-fuse may be sensed at various speeds according to voltage level detection on power-up.

FIG. 10 is a block diagram illustrating a memory system according to certain embodiments. As illustrated, the memory system may include a memory controller 2000 and a dynamic random access memory (DRAM) 1000.

The DRAM 1000 may include the fuse read circuit 100 shown in FIG. 1.

The memory controller 2000 may be connected to a host (not shown). The memory controller 2000 is configured to access the DRAM 1000 in response to a request from the host.

The memory controller 2000 may apply a command, an address, data or another control signal to the DRAM 1000 through a bus B1.

In an exemplary embodiment, the memory controller 2000 may further include components such as a processing unit, a host interface, and a memory interface.

The processing unit controls the overall operation of the memory controller 2000.

The host interface may include a protocol for data exchange between a host and memory controller 2000. For example, memory controller 200 may be configured to communicate with an external device (e.g., host) through one of various interface protocols such as USB (Universal Serial Bus) protocol, MMC (Multimedia Card) protocol, PCI (Peripheral Component Interconnection) protocol, PCI-E (PCI-Express) protocol, ATA (Advanced Technology Attachment) protocol, SATA (Serial ATA) protocol, ESDI (Enhanced Small Disk Interface) protocol, and IDE (Integrated Drive Electronics) protocol.

The memory system in FIG. 10 may be provided as one of various components of ultra mobile PCs (UMPCs), workstations, net-books, personal digital assistants (PDAs), portable computers, web tablets, wireless phones, mobile phones, smart phones, e-books, portable multimedia players (PMPs), portable game consoles, navigation devices, black boxes, digital cameras, digital audio recorders, digital audio players, digital picture recorders, digital picture players, digital video recorders, digital video players, storages constituting digital centers, devices capable of sending and receiving information under wireless environments, one of various electronic devices constituting home networks, one of various electronic devices constituting computer networks, one of various electronic devices constituting telematics networks, radio frequency identification (RFID) devices, or one of various components constituting computing systems.

According to the memory system in FIG. 10, since a fail address in the DRAM 1000 is sensed more stably on slow power-up, system operation stability is improved.

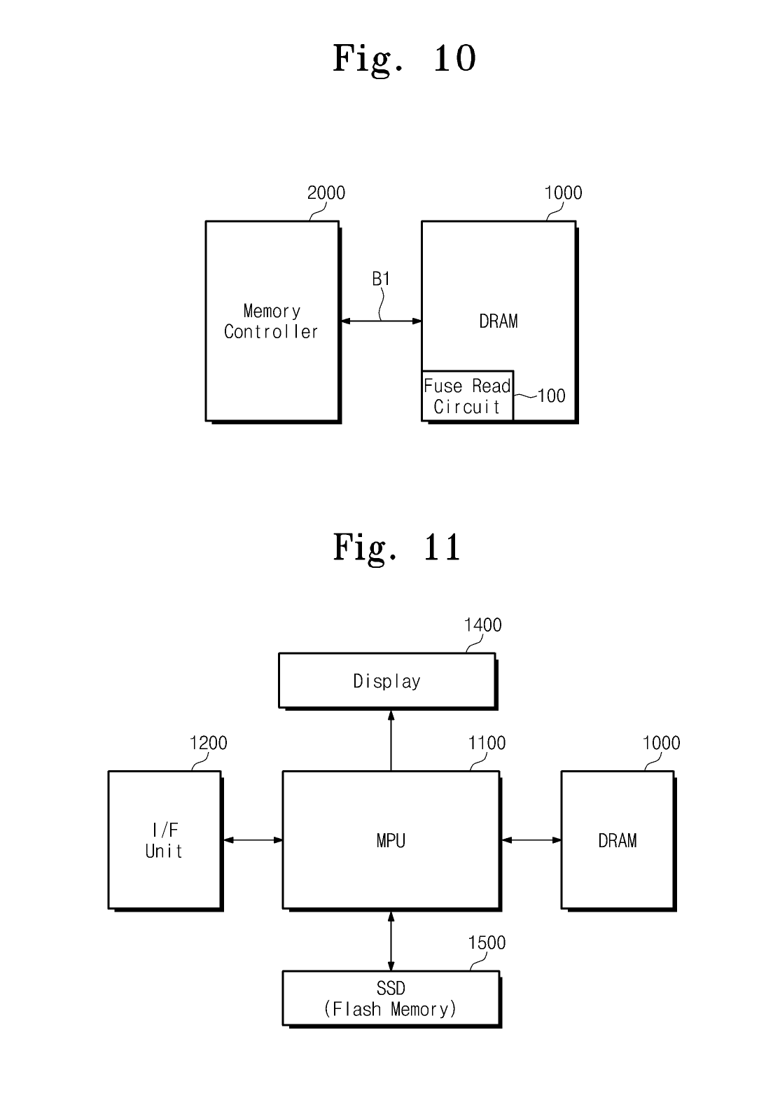

FIG. 11 is a block diagram illustrating a handheld electronic device according to certain embodiments. As illustrated, a handheld electronic device such as a notebook computer may include a microprocessing unit (MPU) 1100, a display 1400, an interface unit 1200, a dynamic random access memory (DRAM) 1000, and a solid-state drive (SSD) 1500.

In certain cases, the MPU 1100, the DRAM 1000, and the SSD 1500 may be manufactured or packaged in a single chip. As a result, the DRAM 1000 and the SSD 1500 may be embedded in the handheld electronic device.

If the handheld electronic device is a handheld communication device, a modem and a transceiver for transmitting/receiving communication data and performing data modulation/demodulation functions may be connected to the interface unit 1200.

The MPU 1100 controls the overall operation of the portable electronic device according to a predetermined program.

The DRAM 1000 is connected to the MPU 1100 through a system bus, and may function as a buffer memory or a main memory. Since the DRAM 1000 may perform functions and operations explained in FIG. 1, sensing speed of a fail address is made relatively low during a slow power-up operation to fuse sensing reliability. Thus, system performance of the handheld electronic device is stabilized and operation reliability thereof is improved.

The display unit 1400 may include a liquid crystal having a backlight, a liquid crystal having an LED light source or a touch screen as an OLED element. The display unit 1400 may function as an output element to display color images such as characters, numbers, pictures, and the like.

The handheld electronic device may be connected to an external communication device through a separate interface. The communication device may be a digital versatile disc (DVD) player, a computer, a set top box (STB), a game machine, a digital camcorder, and the like.

Although not shown in FIG. 11, it will be understood that the handheld electronic device may further include an application chipset, a camera image processor (CIS), and a mobile DRAM, and the like.

A chip of the DRAM 1000 or a chip of the SSD 1500 may be independently or simultaneously mounted using various types of packages. Examples of the packages may include, for example, PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP), and Wafer-Level Processed Stack Package (WSP).

As described in FIG. 11, an SSD is employed. However, various types of nonvolatile storages may be used.

The nonvolatile memory device may store data information having various data forms such as text, graphics, and software code.

The nonvolatile storage may be implemented with, for example, an electrically erasable programmable read-only memory (EEPROM), a flash memory, a magnetic RAM (MRAM), a spin-transfer torque MRAM, a conductive bridging RAM (CBRAM), a ferroelectric RAM (FeRAM), a phase change RAM (PRAM) that is also called ovonic unified memory (OUM), a resistive RAM (RRAM or ReRAM), a nanotube RRAM, a polymer RAM (PoRAM), a nano floating gate memory (NFGM), a holographic memory, a molecular electronics memory device, or an insulator resistance change memory.

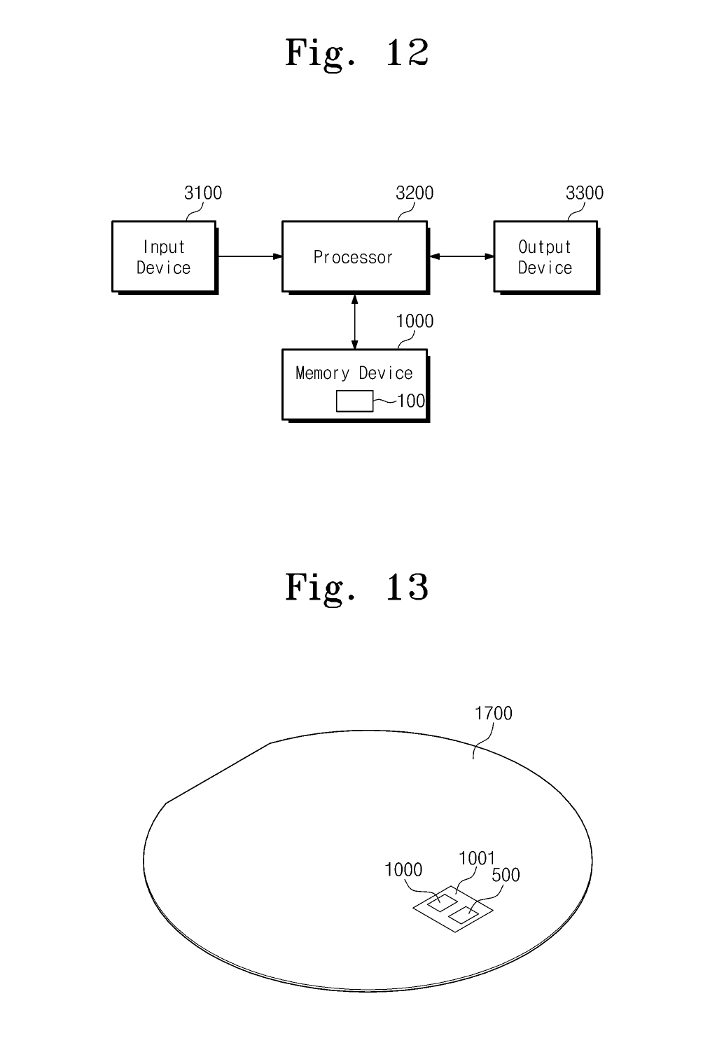

FIG. 12 is a block diagram illustrating an electronic system according to certain embodiments. As illustrated, the electronic system may include an input device 3100, an output device 3300, a processor 3200, and a memory device 1000.

Since the memory device 1000 may include the fuse read circuit 100 in FIG. 1, reliability of redundancy scheme is improved. It is necessary to pay attention to the fact that the memory device 1000 may be integrated into any one of the input device 3100, the output device 3300, and the processor 3200.

Since the electronic system in FIG. 12 may include the fuse read circuit 100 to which the present disclosed embodiments are applied, operation reliability of the electronic system is improved.

FIG. 13 is a block diagram illustrating a semiconductor chip that is mounted on a semiconductor wafer according to certain embodiments. Referring to FIG. 13, a memory device 1000 such as the above-described DRAM may be manufactured together with another electronic device 500 in a chip 1001 on a semiconductor wafer 1700. It should be understood that the memory device 1000 may be processed on a wide variety of semiconductor substrates.

As described in the specification, the memory device 1000 has a relatively slow failed address sensing operation on slow power-up.

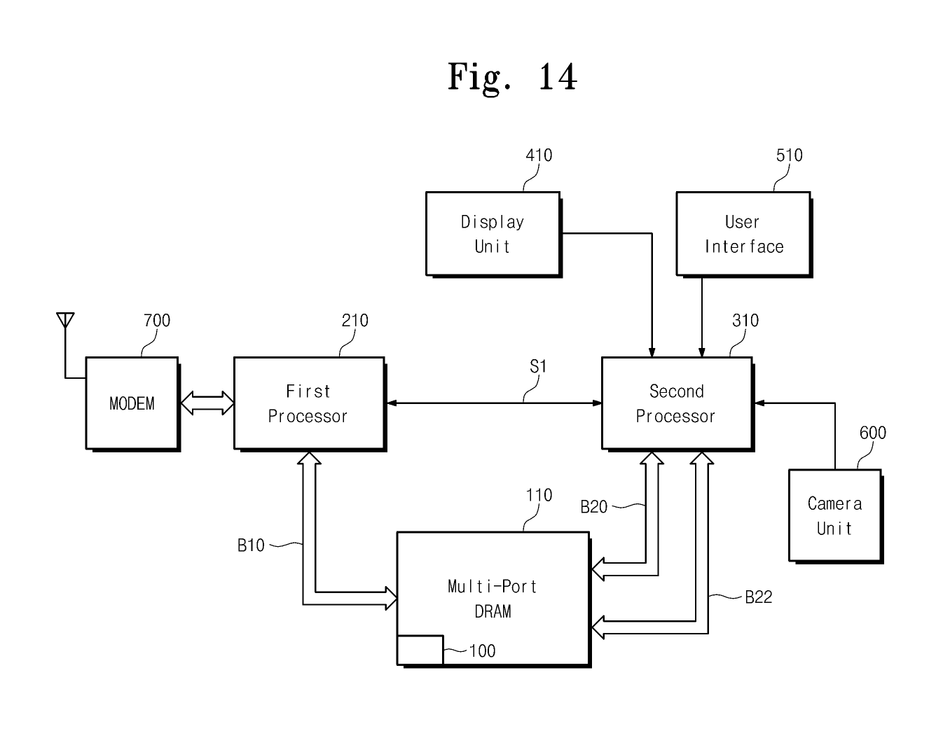

FIG. 14 is a block diagram illustrating a mobile device according to certain embodiments. As illustrated, the mobile device may function as a smart phone and include, for example, a multi-port DRAM 110, a first processor 210, a second processor 310, a display unit 410, a user interface 510, a camera unit 600, and a modem 700.

The multi-port DRAM 110 including the fuse read circuit 100 in FIG. 1 internally has three ports connected to first to third buses B10, B20, and B22 and may be connected to the first processor 210 and the second processor 310.

More specifically, a first port of the multi-port DRAM 110 is connected through the first bus B10 to the first processor 210 that is a baseband processor and a second port of the multi-port DRAM 110 is connected through the second bus B20 to the second processor 310 that is an application processor. A third port of the multi-port DRAM 110 is connected through the third bus B22 to the second processor 310.

Accordingly, a single multi-port DRAM 110 may replace a single storage memory and two DRAMs.

As a result, the multi-port DRAM 110 has three ports and may function as both a conventional DRAM and a conventional flash memory.

In this case, since the multi-port DRAM 110 may sense a fail address relatively slowly on slow power-up, performance and reliability of a mobile device adopting the multi-port DRAM 110 are improved.

Interfaces of the first bus B10 and the third bus B11 may each be a volatile memory (such as DRAM) interface.

An interface of the second bus B20 may be a nonvolatile memory (such as NAND flash memory) interface.

In certain cases, the first and second processors 210 and 310 and the multi-port DRAM 110 may be manufactured or packaged in a single chip. As a result, the multi-port DRAM 110 may be embedded in the mobile device.

If the mobile device is a handheld communication device, a modem 700 for transmitting/receiving communication data and performing data modulation/demodulation functions may be connected to the first processor 210.

A NOR-type or NAND-type flash memory may be connected to the first processor 210 or the second processor 310 to store a large amount of information.

The display unit 410 may include a liquid crystal having a backlight, a liquid crystal having an LED light source or a touch screen as an OLED element. The display unit 410 may function as an output element to display color images such as characters, numbers, pictures, and the like.

Although the mobile device has focused on a mobile communication device, the mobile device may function as a smart card by adding or subtracting components, if necessary.

In the mobile device, a separate interface may be connected to an external communication device. The external communication device may be a digital versatile disc (DVD) player, a computer, a set top box (STB), a game machine, a digital camcorder or the like.

The camera unit 600 includes a camera image processor (CIS) and is connected to the second processor 310.

Although not shown in FIG. 14, it should be apparent to those skilled in the art that the mobile device may further include an application chipset or a mobile DRAM.

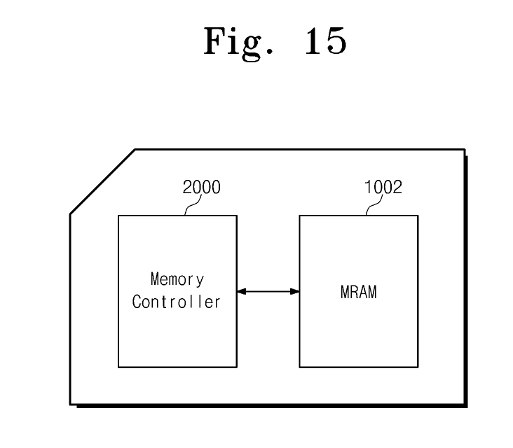

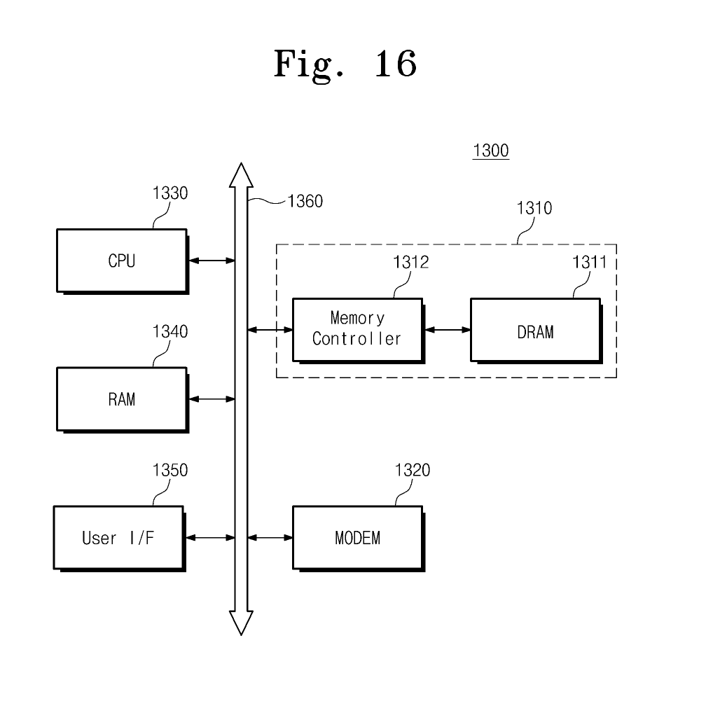

FIG. 15 is a block diagram illustrating a memory card according to certain embodiments. As illustrated, the memory card may include a memory controller 2000 and an MRAM 1002. Other than memory cells, the MRAM 1002 may have the same function blocks of a DRAM as described in the disclosed embodiments. Thus, operation performance of the memory card may be improved on slow power-up.

The memory controller 2000 writes write data required for operation of the memory card into a selected memory cell of the MRAM 1002. The MRAM 1002 reads out data stored in the selected memory cell when receiving a read command from the memory controller 2000.

FIG. 16 is a block diagram illustrating a computing device 1300 according to certain embodiments. As illustrated, the computing device 1300 may include a memory system 1310 including a DRAM 1311. The computing device 1300 may include an information processing device, a computer or the like. For example, the computing device 1300 may include, for example, a memory system 1310 and a modem 1320, a central processing unit (CPU) 1330, a random access memory (RAM), and a user interface (User I/F) 1350 which are each electrically connected to a system bus 1360. Data processed by the CPU 1330 or externally input data may be stored in the memory system 1310.

The computing device 1300 may function as a solid-state disk (SSD), a camera image processor, and other application chipsets. For example, the memory system 1310 may include an SSD. In this case, the computing device 1300 may stably and reliably store a large amount of data in the memory system 1310.

Together with the memory controller 1312, the DRAM 1311 constituting the memory system 1310 may perform a reliable fail address sensing operation even during a slow power-up operation. Thus, performance of the computing device 1300 is improved.

According to an exemplary configuration of the disclosed embodiments, fuse sensing reliability is improved because sensing speed is relatively slow during a slow power-up operation.

While the disclosure has been particularly shown and described with reference to exemplary embodiments thereof, it will be apparent to those of ordinary skill in the art that various changes in form and detail may be made therein without departing from the spirit and scope of the invention as defined by the following claims.

What is claimed is:

1. A semiconductor memory device comprising:
a memory cell array including a normal memory cell array and a spare memory cell array;
an anti-fuse circuit supplied with a first voltage and configured to store fail address information associated with a defective memory cell in the normal memory cell array and configured to sense the fail address information in response to a clock signal applied during a power-up period; and
a fuse read circuit including a clock generator supplied with a second voltage, the fuse read circuit configured to detect respective levels of the first and second voltages during the power-up period, to generate the clock signal, and to read the sensed fail address information from the anti-fuse circuit in response to the clock signal,
wherein the clock signal has a period that varies in response to the detected levels of the first and second voltages.

2. The semiconductor memory device as set forth in claim 1, wherein the defective memory cell is a dynamic random access memory (DRAM) cell.

3. The semiconductor memory device as set forth in claim 1, wherein the clock generator is configured to generate the clock signal, and
wherein the fuse read circuit further includes a clock period control circuit configured to detect respective levels of the first voltage and second voltage during the power-up period, and to generate a clock period control signal based on a result of the detection.

4. The semiconductor memory device as set forth in claim 3, wherein the fuse read circuit further includes:
a fuse information storage circuit configured to store the sensed fail address information in response to the clock signal.

5. The semiconductor memory device as set forth in claim 3, wherein the fuse information storage circuit includes a shift register.

6. The semiconductor memory device as set forth in claim 3, wherein a level of the first voltage is higher than a level of the second voltage after the power-up period.

7. The semiconductor memory device as set forth in claim 6, wherein the clock period control circuit includes:
a first delay part supplied with the second voltage and configured to receive and delay the clock signal;
a second delay part supplied with the first voltage and configured to receive and delay the clock signal; and
a phase detector configured to compare a phase of a first output clock delayed by the first delay part with a phase of a second output clock delayed by the second delay part to generate the clock period control signal.

8. The semiconductor memory device as set forth in claim 7, wherein the phase detector is configured to generate the clock period control signal that causes the clock signal to have a period longer than a reference period when the phase of the first output clock is ahead of the phase of the second output clock.

9. The semiconductor memory device as set forth in claim 7, wherein the phase detector is configured to generate the clock period control signal that causes the clock signal to have a period equal to or shorter than a reference period when the phase of the first output clock is lagged behind the phase of the second output clock.

10. The semiconductor memory device as set forth in claim 7, wherein a sensing speed of the fail address information is slower when a level of the first voltage is lower than a level of the second voltage during the power-up period.

11. A method of reading data from an anti-fuse circuit of a semiconductor memory device, the method comprising:
during a power-up operation mode, applying a first voltage to a clock generator of the semiconductor memory device and applying a second voltage to the anti-fuse circuit;
controlling a frequency of a driving clock applied to an anti-fuse circuit to be less than a reference frequency of the driving clock when a level of the second voltage is less than a level of the first voltage during the power-up operation mode; and
reading the data of the anti-fuse circuit in response to the driving clock.

12. The method as set forth in claim 11, wherein a level of the second voltage is higher than a level of the first voltage after the power-up operation mode is terminated.

13. The method as set forth in claim 11, wherein a speed of reading the data is reduced by decreasing a frequency of the driving clock.

14. The method as set forth in claim 11, wherein the data is a failed address.

15. A method of reading data from a fuse storage circuit of a memory device, the fuse storage circuit including a plurality of fuses, the method comprising:
initiating a power-up operation of the memory device by providing first and second voltages to the fuse storage circuit and a clock generator of the memory device, respectively; and
during the power-up operation,
generating a clock signal by the clock generator, the clock signal having a period; and
reading the data stored in the plurality of fuses of the fuse storage circuit in response to the clock signal,
wherein the period of the clock signal is longer than a reference period when a level of the first voltage is less than a level of the second voltage.

16. The method as set forth in claim 15, wherein generating the clock signal includes:
comparing a first internal clock signal generated by a first delay circuit receiving the second voltage and the clock signal with a second internal clock signal generated by a second delay circuit receiving the first voltage and the clock signal.

17. The method as set forth in claim 15, wherein a speed of reading the data in response to the clock signal having a longer period than the reference period is slower than a speed of reading the data in response to the clock signal having the same or a shorter period than the reference period.

18. The method as set forth in claim 15, wherein the data is a failed address.

19. The method as set forth in claim 15, wherein a level of the first voltage is greater than a level of the second voltage after the power-up operation is completed.

20. The method as set forth in claim 15, wherein the fuse storage circuit includes a plurality of anti-fuses.
